(19) United States
(12) Patent Application Publication
(10) Pub. No.: US 2022/0002156 A1
(43) Pub. Date: Jan. 6, 2022

(54) METHOD FOR TRANSFERRING GRAPHENE FILM

(71) Applicant: ZHEJIANG UNIVERSITY, Hangzhou (CN)

(72) Inventors: Mingsheng Xu, Hangzhou (CN); Han Xiao, Hangzhou (CN)

(21) Appl. No.: 17/478,931

(22) Filed: Sep. 19, 2021

Related U.S. Application Data
(63) Continuation of application No. PCT/CN2020/103301, filed on Jul. 21, 2020.

(30) Foreign Application Priority Data
Feb. 12, 2020 (CN) 202010088334.4

(51) Int. Cl. C01B 32/182; B05D 1/00; B05D 3/10; H01L 31/18; C23F 1/18; C23F 1/30

(52) U.S. Cl. CPC C01B 32/182; B05D 1/005; B05D 3/107; H01L 31/18; B05D 2203/30; C23F 1/30; B05D 2350/60; B05D 2420/02; B05D 2518/00; C23F 1/18

(57) ABSTRACT

A method for transferring a graphene film is provided. The method includes spin-coating a cera alba containing solution onto a surface of the graphene film on a metal substrate to form a cera alba layer as a supporting layer, so as to obtain a first stack having the cera alba layer, the graphene film and the metal substrate in sequence; removing the metal substrate with an etching solution to obtain a second stack having the cera alba layer and the graphene film, transferring the second stack onto a target substrate to obtain a third stack having the second stack and the target substrate, and drying the third stack; removing the cera alba layer with an organic solvent. By using natural non-toxic harmless cera alba as a supporting material, it is possible to obtain the graphene film with a clean and intact surface and low sheet resistance.

### CROSS-REFERENCE TO RELATED APPLICATIONS

This application is a continuation of PCT Patent Application No. PCT/CN2020/103301, filed on Jul. 21, 2020, entitled “METHOD FOR TRANSFERRING GRAPHENE FILM,” which claims foreign priority of Chinese Patent Application No. 202010088334.4, filed with the China National Intellectual Property Administration (CNIPA) on Feb. 12, 2020, the entire content of which are hereby incorporated by reference in their entireties.

### TECHNICAL FIELD

The present disclosure relates to two-dimensional nanomaterial technologies, and more particularly to a method for transferring a graphene film, a method for transferring a two-dimensional material film and a photodetector.

### BACKGROUND

Graphene, as a single-layer form of carbon that possesses excellent electrical, optical, mechanical, and thermal properties, as well as stable adjustability, has attracted enormous attention from global scientific and industrial communities. These properties render graphene as a promising material in a wide range of applications, especially in electronic and photoelectronic devices such as photodetectors and optical modulators.

Several methods have been explored to synthesize large-scale graphene films, such as chemical vapor deposition (CVD) and epitaxial growth on SiC substrates. Among these methods, CVD growth on catalytic metal substrates (e.g., Cu, Ni) is generally considered to be the most feasible one to prepare graphene with high quality and high yield. In order to integrate CVD-synthesized graphene films into modern electronic, optoelectronic, and optical devices and energy storage devices, it is a prerequisite to develop a reproducible method for transferring graphene films onto target substrates with neatness and integrity.

### SUMMARY

Embodiments of the present disclosure seek to solve at least one of the problems existing in the related art to at least some extent.

In an aspect, a method for transferring a graphene film is provided. The method includes spin-coating a cera alba (CA) containing solution onto a surface of the graphene film on a metal substrate to form a cera alba layer as a supporting layer, so as to obtain a first stack having the cera alba layer, the graphene film and the metal substrate in sequence; removing the metal substrate with an etching solution to obtain a second stack having the cera alba layer and the graphene film, transferring the second stack onto a target substrate to obtain a third stack having the second stack and the target substrate, and drying the third stack; and removing the cera alba layer with an organic solvent to complete a transfer of the graphene film.

In another aspect, a method for transferring a two-dimensional material film is provided. The method includes coating a cera alba containing solution onto a surface of the two-dimensional material film on a first substrate to form a first stack having a cera alba layer; removing the first substrate with an etching solution to obtain a second stack, transferring the second stack onto a target substrate to obtain a third stack; and removing the cera alba layer with an organic solvent.

In another aspect, a photodetector is provided. The photodetector includes a substrate; a graphene layer formed on at least a part of a surface of the substrate; a PbI₂ layer formed on a remaining part of the surface of the substrate and connected to the graphene layer; and a source and a drain formed on the graphene layer, respectively. The graphene layer is transferred onto the at least a part of the surface of the substrate by using a cera alba supporting layer.

The above summary of the present disclosure is not intended to describe each disclosed embodiment or every implementation of the present disclosure. The Figures and the detailed description which follow more particularly exemplify illustrative embodiments.

Additional aspects and advantages of embodiments of present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of embodiments of the present disclosure will become apparent and more readily appreciated from the following descriptions made with reference to the drawings, in which:

FIG. 1 is a flow diagram of a method for transferring a graphene film according to an embodiment of the present disclosure;

FIG. 2 is a flow diagram of a method for transferring a two-dimensional material film according to an embodiment of the present disclosure;

FIG. 3 is a schematic diagram of a transfer process of a graphene film according to an embodiment of the present disclosure;

FIG. 4 is an optical microscope (OM) image of a graphene film obtained in the Inventive Example 1;

FIG. 5A and FIG. 5B are X-ray photoelectron spectroscopy (XPS) spectra of graphene films obtained in the Inventive Example 1 and Comparative Example 1, respectively;

FIG. 6A and FIG. 6B are sheet resistance spatial distribution images of graphene films obtained in the Inventive Example 1 and Comparative Example 1, respectively;

FIG. 7A is an optical microscope (OM) image of a graphene film obtained in the Inventive Example 1;

FIG. 7B is Raman spectra of a graphene film obtained in the Inventive Example 1;

FIG. 8 is an optical microscope (OM) image of a graphene film obtained in Comparative Example 1;

FIG. 9 is an optical microscope (OM) image of a graphene film obtained in Comparative Example 2.

FIG. 10A is a schematic diagram of a Gr-PbI₂-Gr photodetector according to an embodiment of the present disclosure.

FIG. 10B is an OM image of a Gr-PbI₂-Gr photodetector according to an embodiment of the present disclosure.

FIG. 10C illustrates I_{ds}-V_{ds} curves of a Gr-PbI₂-Gr photodetector according to an embodiment of the present disclosure with different V_{g}.

FIG. 10D illustrates I_{ds}-V_{ds} curves of an Au-PbI₂-Au photodetector with different Vg.

FIG. 10E illustrates I-t curves of a Gr-PbI₂-Gr photodetector according to an embodiment of the present disclosure with different illumination power densities.

FIG. 10F is one cycle I-t curve of a Gr-PbI₂-Gr photodetector according to an embodiment of the present disclosure.

FIG. 11 is an optical microscope (OM) image of a h-BN film obtained in the Inventive Example 2; and

FIG. 12 is an optical microscope (OM) image of a h-BN film obtained in Comparative Example 4.

### DETAILED DESCRIPTION OF THE EMBODIMENTS

Reference will be made in detail to embodiments of the present disclosure. The embodiments described herein with reference to drawings are explanatory, illustrative, and used to generally understand the present disclosure. The embodiments shall not be construed to limit the present disclosure. Experiment methods without specific conditions in the following examples generally follow conventional conditions or the conditions recommended by manufacturers.

A graphene film is a planar film in which carbon atoms form a hexagonal honeycomb lattice with sp² hybrid orbitals. The graphene film is a two-dimensional film with a thickness of one carbon atom, and thus can also be referred to as a monolayer graphene film.

Since graphene films are transparent and highly fragile, polymer supporting layers need to be introduced to make the graphene films visible and protect the graphene films from fractures during the transfer process.

According to the basic principles of graphene film transfer by polymer supporting layers, an ideal supporting material should satisfy the following two requirements to enable both clean and intact graphene transfer. First, the supporting material should have a sufficient solubility in a certain chemical solvent, so that it can be easily spin-coated onto a surface of a graphene film and completely removed from the surface of the graphene film after being transferred. Second, the supporting layer should form a strong enough interaction with graphene to avoid structural damages during the transfer process.

In an aspect, a method for transferring a graphene film is provided. As shown in FIG. 1, the method includes steps as follows:

In step 101, a cera alba (CA) containing solution is spin-coated onto a surface of the graphene (Gr) film on a metal substrate to form a cera alba layer as a supporting layer, so as to obtain a first stack having the cera alba layer, the graphene film and the metal substrate in sequence.

In step 102, the metal substrate is removed with an etching solution to obtain a second stack having the cera alba layer and the graphene film, the second stack is transferred onto a target substrate to obtain a third stack having the second stack and the target substrate, and the third stack is dried.

In step 103, the cera alba layer is removed with an organic solvent to complete a transfer of the graphene film.

Accordingly, the graphene film is transferred with neatness and integrity, such that the obtained graphene film has good quality.

Cera alba is a natural material derived from bee's honeycomb, which is environmentally friendly and cheap. Cera alba is mainly composed of cerotic acid and myricyl palmitate with an approximate chemical formula of C₁₅H₃₁COOC₃₀H₆₁.

In an embedment, the graphene film includes one to ten layers of monolayer graphene, preferably one layer of monolayer graphene.

In an embodiment, a cera alba (CA) containing solution is spin-coated onto a surface of the graphene (Gr) film on a metal substrate to form a cera alba layer as a supporting layer, so as to obtain a first stack having the cera alba layer, the graphene film and the metal substrate in sequence, i.e., a CA/Gr/metal stack. In an embodiment, the metal substrate is a copper (Cu) foil, and the first stack is a CA/Gr/Cu stack.

In an embodiment, spin-coating the cera alba containing solution onto the surface of the graphene film on the metal substrate to form the cera alba layer includes spin-coating the cera alba containing solution onto the surface of the graphene film at a temperature higher than or equal to 60° C., followed by standing to form the cera alba layer. Cera alba is dissolved in an organic solvent, such as chloroform, diethyl ether, or benzene, to form the cera alba containing solution. In an embodiment, a concentration of the cera alba containing solution is less than or equal to 1 g·mL⁻¹, preferably is 0.2 g·mL⁻¹. As an example, the cera alba containing solution in chloroform at a concentration of 0.2 g·mL⁻¹ is uniformly spin-coated onto the surface of the graphene film at a rotation speed of 500 rpm for 10 s and 4000 rpm for 120 s in succession, followed by standing at room temperature for 10 min.

In an embodiment, the spin-coating is performed with hot air at a temperature higher than or equal to 60° C., preferably higher than or equal to 65° C., more preferably higher than or equal to 70° C. As an example, hot air at a temperature of 60° C. is used.

In an embodiment, the cera alba layer has a thickness less than or equal to 10μm, preferably of 1 μm. The thickness of the cera alba layer can be adjusted by changing spin-coating parameters, such as the concentration of the cera alba containing solution, the rotation speed, the spin-coating duration, spin-coating times, and the like.

In an embodiment, the first stack is placed into an etching solution to remove the metal substrate so as to obtain a second stack having the cera alba layer and the graphene film, i.e., a CA/Gr stack. In an embodiment, the etching solution is selected from at least one of an ammonium persulfate solution and a ferric chloride solution. Preferably, the etching solution is an ammonium persulfate solution at a concentration of 0.5 mol·L⁻¹. For example, after being solidified at room temperature for 10 min, the first stack is floated in an etching solution for about 1 h to completely remove the metal substrate. After the metal substrate is removed, the second stack is washed with deionized water for several times, e.g., 3 times to remove the etching solution.

In an embodiment, the second stack is transferred onto a target substrate to obtain a third stack having the second stack and the target substrate, i.e., a CA/Gr/substrate stack, and the third stack is dried. In an embodiment, the target substrate is a silicon substrate having a silicon oxide layer, i.e., a SiO₂/Si substrate, and the third stack is a CA/Gr/SiO₂/Si stack.

In an embodiment, the third stack is dried at room temperature for more than 12 h. To ensure a solid contact, the third stack was baked at 40° C. for 30 min.

After being dried, the third stack is placed in an organic solvent to remove the cera alba layer. In an embodiment, the organic solvent is selected from one or more of chloroform, diethyl ether, and benzene, preferably chloroform. In an embodiment, the cera alba layer is removed with chloroform at a temperature of 40° C.

The advantages of the present method lie in that the graphene film has better integrity, less remaining residues appearing on a surface of the graphene film, lower sheet resistance, and higher quality, as compared to graphene transfer methods in the related art. Moreover, cera alba has lower cost, for example, the price of cera alba is only 6.35% of that of PMMA. In addition, cera alba is environmentally friendly, and the method is easy to perform. In other words, by using natural non-toxic harmless cera alba as a supporting material, it is possible to obtain a graphene film with a clean and intact surface and low sheet resistance.

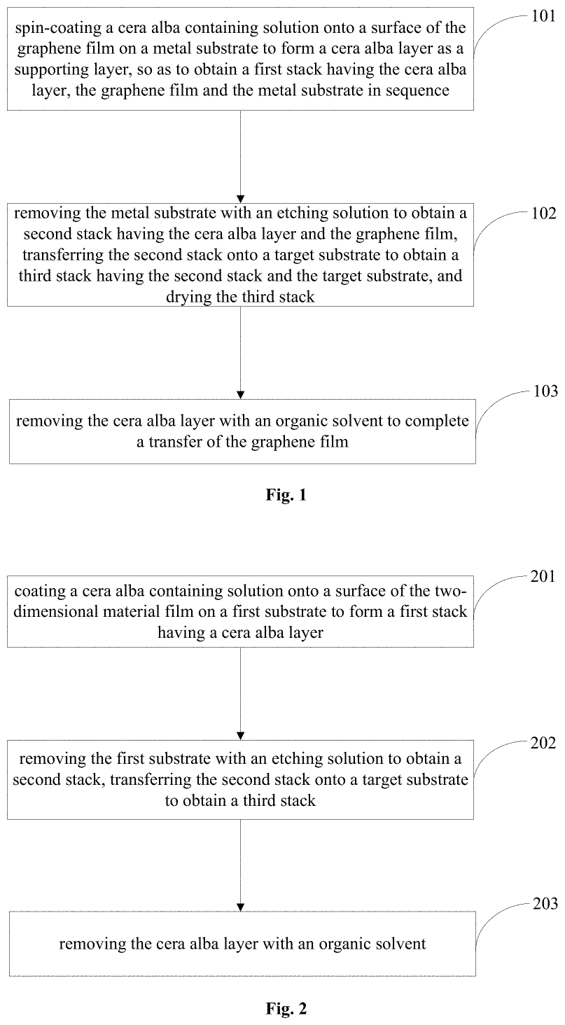

In another aspect, a method for transferring a two-dimensional material film is provided. As shown in FIG. 2, the method includes steps as follows:

In step 201, a cera alba containing solution is coated onto a surface of the two-dimensional material film on a first substrate to form a first stack having a cera alba layer.

In step 202, the first substrate is removed with an etching solution to obtain a second stack, the second stack is transferred onto a target substrate to obtain a third stack.

In step 203, the cera alba layer is removed with an organic solvent.

In an embodiment, the two-dimensional material film includes at least one of graphene, transition metal dichalcogenides, hexagonal boron nitride (h-BN), silicene, germanene, black phosphorus (BP), borophene, stannene, transition metal thiophosphates, ternary transition metal chalcogenides, transition metal halides, transition metal carbides, transition metal nitrides, transition metal carbonitrides, layered double hydroxides, metal-organic framework (MOF), antimonene, derivatives thereof, and combinations thereof. Preferably, the two-dimensional material film is a graphene film or a hexagonal boron nitride (h-BN) film.

In an embodiment, a cera alba (CA) containing solution is coated onto a surface of the two-dimensional (2D) material film on a first substrate to form a first stack having a cera alba layer. The first stack has the cera alba layer, the two-dimensional material film and the first substrate in sequence, i.e., a CA/2D/metal stack. In an embodiment, the first substrate is a copper (Cu) foil, and the first stack is a CA/2D/Cu stack.

In an embodiment, coating the cera alba containing solution onto the surface of the two-dimensional material film on the first substrate to form the first stack having the cera alba layer includes spin-coating the cera alba containing solution onto the surface of the two-dimensional material film at a temperature higher than or equal to 60° C., followed by standing to form the cera alba layer. Cera alba is dissolved in an organic solvent, such as chloroform, diethyl ether, or benzene, to form the cera alba containing solution. In an embodiment, a concentration of the cera alba containing solution is less than or equal to 1 g·mL⁻¹, preferably is 0.2 g·mL⁻¹. As an example, the cera alba containing solution in chloroform at a concentration of 0.2 g·mL⁻¹ is uniformly spin-coated onto the surface of the two-dimensional material film at a rotation speed of 500 rpm for 10 s and 4000 rpm for 120 s in succession, followed by standing at room temperature for 10 min.

In an embodiment, the spin-coating is performed with hot air at a temperature higher than or equal to 60° C., preferably higher than or equal to 65° C., more preferably higher than or equal to 70° C. As an example, hot air at a temperature of 60° C. is used.

In an embodiment, the cera alba layer has a thickness less than or equal to 10 μm, preferably is 1 μm. The thickness of the cera alba layer can be adjusted by changing spin-coating parameters, such as the concentration of the cera alba containing solution, the rotation speed, the spin-coating duration, spin-coating times, and the like.

In an embodiment, the first stack is placed into an etching solution to remove the first substrate so as to obtain a second stack having the cera alba layer and the two-dimensional material film, i.e., a CA/2D stack. In an embodiment, the etching solution is selected from at least one of an ammonium persulfate solution and a ferric chloride solution. Preferably, the etching solution is an ammonium persulfate solution at a concentration of 0.5 mol·L⁻¹. For example, after being solidified at room temperature for 10 min, the first stack is floated in an etching solution for about 1 h to completely remove the first substrate. After the first substrate is removed, the second stack is washed with deionized water for several times, e.g., 3 times to remove the etching solution.

In an embodiment, the second stack is transferred onto a target substrate to obtain a third stack having the second stack and the target substrate, i.e., a CA/2D/substrate stack, and the third stack is dried. In an embodiment, the target substrate is a silicon substrate having a silicon oxide layer, i.e., a SiO₂/Si substrate, and the third stack is a CA/2D/SiO₂/Si stack.

In an embodiment, the third stack is dried at room temperature for more than 12 h. To ensure a solid contact, the third stack is baked at 40° C. for 30 min.

After being dried, the third stack is placed in an organic solvent to remove the cera alba layer. In an embodiment, the organic solvent is selected from one or more of chloroform, diethyl ether, and benzene, preferably chloroform. In an embodiment, the cera alba layer is removed with chloroform at a temperature of 40° C.

The advantages of the present method lie in that the two-dimensional material film has better integrity, less remaining residues appearing on a surface of the two-dimensional material film, lower sheet resistance, and higher quality, as compared to transfer methods in the related art. In other words, by using natural non-toxic harmless cera alba as a supporting material, it is possible to obtain a two-dimensional material film with a clean and intact surface and low sheet resistance.

In another aspect, a photodetector is provided. The photodetector includes a substrate; a graphene layer formed on at least a part of a surface of the substrate; a PbI₂ layer formed on a remaining part of the surface of the substrate and connected to the graphene layer; and a source and a drain formed on a surface of the graphene layer, respectively. The graphene layer is transferred onto the at least a part of the surface of the substrate by using a cera alba supporting layer. In an embodiment, the graphene layer is transferred onto the at least a part of the surface of the substrate by the method for transferring the graphene film according to embodiments of the present disclosure.

The advantages of the present photodetector lie in that such a graphene layer transferred by using a CA supporting layer enables better contact and gate tunability than traditional Au electrodes and leads to a 135% improvement on the responsivity of the UV photodetector.

Determination Methods

The optical microscope (OM) images were measured on Nikon LV100 POL.

Surface elemental composition was characterized by X-ray photoelectron spectroscopy (XPS) (Thermo ESCALAB 250Xi).

Sheet resistances were measured by a four-probe resistance measurement system (ST2253, Suzhou, China), which was calibrated by measuring standard samples.

All Raman spectrum and mapping were acquired on a laser confocal Raman spectrometer (Renishaw InVia) with a 532 nm laser.

Electrical properties were characterized with a homemade system including a photodetector (818 UV, Newport), a pulse generator (RIGOL DG5100), an oscilloscope (Wavesurfer 3024, Teledyne) and a power meter (Newport 1931-C).

Experimental Part

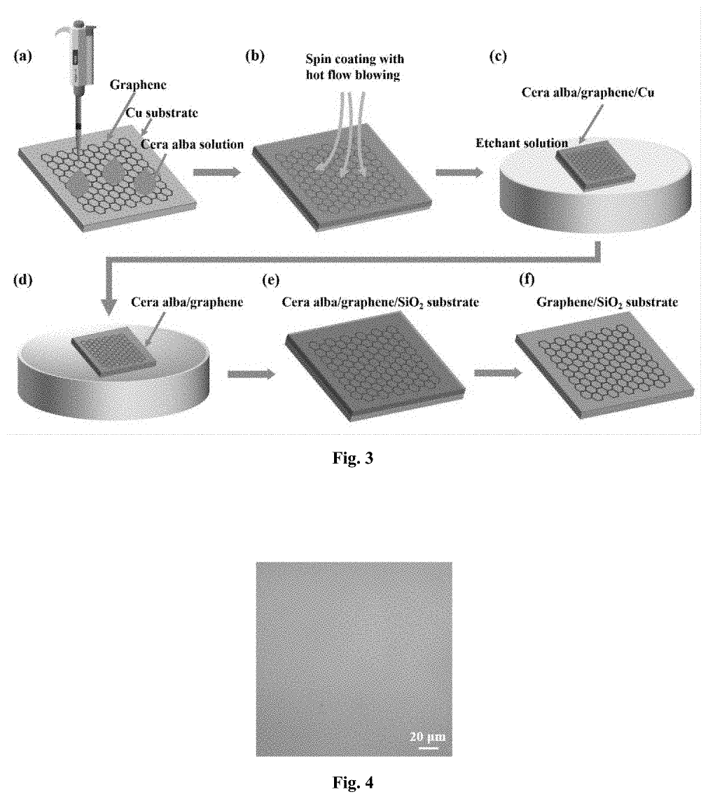

Steps of methods for transferring graphene films in the Inventive Example 1 and Comparative Examples 1 and 2 will be described below. A method for transferring a graphene film in the Inventive Example 1 is shown in FIG. 3 and will be described in detail below. A graphene film sample having a graphene (Gr) film and a copper (Cu) substrate is bonded onto a glass plate with a tape. A cera alba (CA) containing solution is uniformly spin-coated onto the graphene film sample with hot air at a temperature of 60° C. or more to form a CA layer. The copper substrate is removed with an ammonium persulfate etching solution to obtain a CA/Gr stack. The CA/Gr stack is washed with deionized water, and collected onto a target substrate to obtain a CA/Gr/substrate stack. The CA/Gr/substrate stack is dried, and placed in chloroform as an organic solvent to remove the CA layer so as to obtain a Gr/substrate stack. The Gr/substrate stack is dried by nitrogen gas. The basic operation steps of methods of Comparative Examples 1 and 2 are substantially the same as those of the Inventive Example 1, except supporting materials and organic solvents.

### INVENTIVE EXAMPLE 1

A method for transferring a graphene film in the Inventive Example 1 will be described as follows:

A graphene film sample having a graphene (Gr) film and a copper (Cu) foil grown was bonded onto a glass plate with a tape. A cera alba (CA) containing solution in chloroform at a concentration of 0.2 g·mL⁻¹ was uniformly spin-coated onto the graphene film sample at a rotation speed of 4000 rpm for 120 s, followed by standing at room temperature for 10 min to form a CA/Gr/Cu stack having a CA layer. The thickness of the CA layer was about 1 μm.

The tape was peeled off. The CA/Gr/Cu stack was re-fixed onto the glass plate with the CA layer contacting the glass plate, and placed into an oxygen plasma cleaner for 20 min to remove graphene on a backside of the Cu foil in the CA/Gr/Cu stack.

The CA/Gr/Cu stack was taken from the glass plate, and placed into an ammonium persulfate solution as an etching solution for about 1 h to etch the Cu foil. After the copper foil was completely removed, the sample was washed with deionized water for several times to obtain a CA/Gr stack.

A silicon wafer having an oxide layer with a thickness of 300 nm was cut into small square pieces with a size of about 1 cm×1 cm. Then, the piece was washed, and treated by oxygen plasma for using as a target substrate, i.e., a SiO₂/Si substrate.

The CA/Gr stack was collected onto the target substrate to obtain a CA/Gr/substrate stack. The CA/Gr/substrate stack was dried, and placed in chloroform as an organic solvent at a temperature of 40° C. to remove the CA layer so as to obtain a Gr/substrate stack. The Gr/substrate stack was finally dried by nitrogen gas.

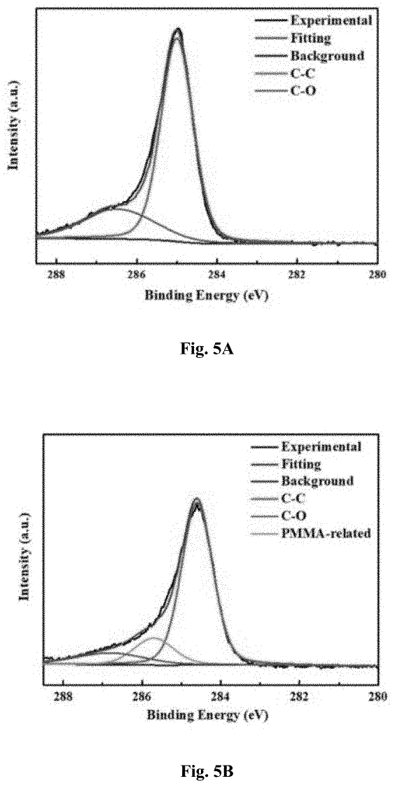

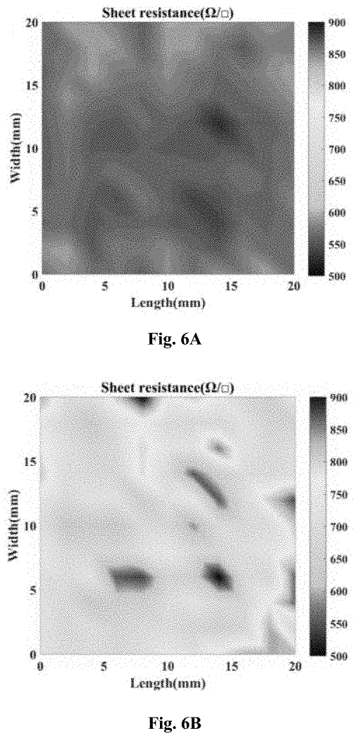

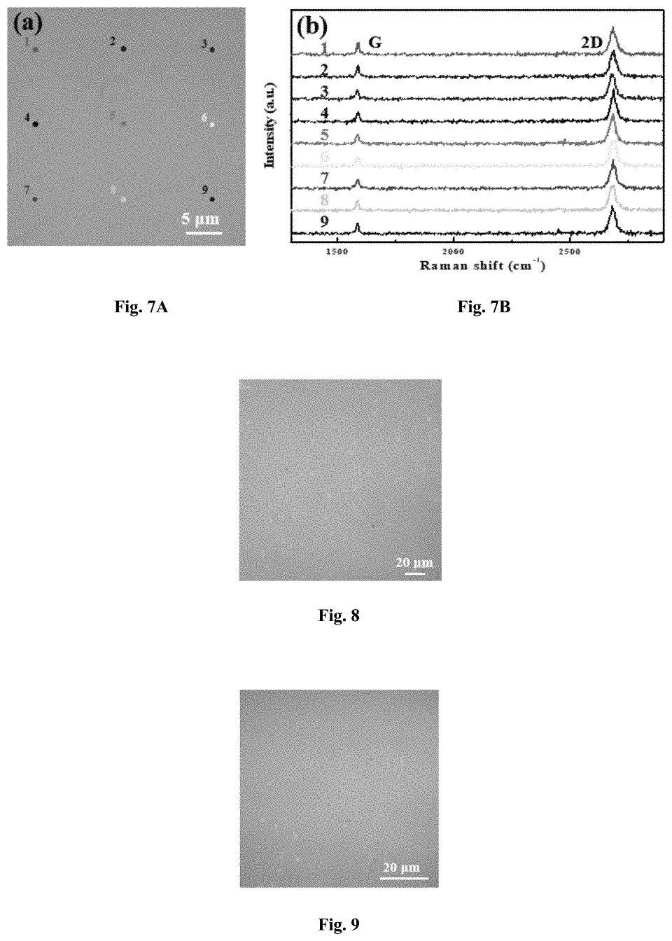

FIG. 4 is an optical microscope (OM) image of a graphene film obtained in the Inventive Example 1. FIG. 5A is an X-ray photoelectron spectroscopy (XPS) spectrum of a graphene film obtained in the Inventive Example 1. FIG. 6A is a sheet resistance spatial distribution image of a graphene film obtained in the Inventive Example 1. FIG. 7A is an optical microscope (OM) image and Raman spectra of a graphene film obtained in the Inventive Example 1. FIG. 7B is Raman spectra of a graphene film obtained in the Inventive Example 1.

Raman spectroscopy is an effective way to characterize the layer numbers, stacking, defects and edge structures of the graphene film. In order to avoid deviations caused by test point selection, as shown in FIG. 7A, nine equally spaced test points were selected for the graphene film transferred by the CA supporting layer. As depicted in FIG. 7B, characteristic Raman peaks of G and 2D peaks are located at 1586 cm⁻¹ and 2686 cm⁻¹ for all nine points. Generally, Raman inactive D peak at about 1350 cm⁻¹ becomes active when structural defects exist. No significant D peak is detected in the Raman spectra of the graphene film transferred by the CA supporting layer, which indicates that the transfer process may not induce additional structural damages or impurities, except the grown-induced defects such as wrinkles and grain boundary.

### COMPARATIVE EXAMPLE 1

A method for transferring a graphene film in Comparative Example 1 will be described as follows:

A graphene film sample having a graphene (Gr) film and a copper (Cu) foil grown was bonded onto a glass plate with a tape. A PMMA containing solution in anisole at a mass fraction of 4% was uniformly spin-coated onto the graphene film sample at a rotation speed of 3000 rpm, followed by heating on a heating stage at a temperature of 70° C. for 10 min to form a PMMA/Gr/Cu stack having a PMMA layer.

The tape was peeled off. The PMMA/Gr/Cu stack was re-fixed onto the glass plate with the PMMA layer contacting the glass plate, and placed into an oxygen plasma cleaner for 20 min to remove graphene on a backside of the Cu foil in the PMMA/Gr/Cu stack.

The PMMA/Gr/Cu stack was taken from the glass plate, and placed into an ammonium persulfate solution as an etching solution for about 1 h to each the Cu foil. After the copper foil was completely removed, the sample was washed with deionized water for several times to obtain a PMMA/Gr stack.

A silicon wafer having an oxide layer with a thickness of 300 nm was cut into small square pieces with a size of about 1 cm×1 cm. Then, the piece was washed, and treated by oxygen plasma for using as a target substrate.

The PMMA/Gr stack was collected onto the target substrate to obtain a PMMA/Gr/substrate stack. The PMMA/Gr/substrate stack was dried, heated on the heating stage at a temperature of 40° C. for 30 min, and placed into acetone as an organic solvent for 30 min to remove the PMMA layer so as to obtain a Gr/substrate stack. The Gr/substrate stack was finally dried by nitrogen gas.

FIG. 5B is an X-ray photoelectron spectroscopy (XPS) spectrum of a graphene film obtained in Comparative Example 1. FIG. 6B is a sheet resistance spatial distribution image of a graphene film obtained in Comparative Example 1. FIG. 8 is an optical microscope (OM) image of a graphene film obtained in Comparative Example 1. As can be seen from FIG. 8, while the integrity of the graphene film is ensured, more PMMA particles remain on a surface of the graphene film, since it is difficult to remove PMMA with an organic solvent in one step due to the strong binding force between PMMA and graphene. This conclusion is also proved by PMMA characteristic peaks detected in the X-ray photoelectron spectroscopy (XPS) spectrum shown in FIG. 5B. This kind of polymer residues is detrimental to high-performance graphene-based devices, since it impairs graphene carrier mobility, augments the contact resistance, and weakens the interlayer coupling when constructing two-dimensional (2D) Van der Waals heterostructures.

### COMPARATIVE EXAMPLE 2

A method for transferring a graphene film in Comparative Example 2 will be described as follows:

A graphene film sample having a graphene (Gr) film and a copper (Cu) foil grown was bonded onto a glass plate with a tape. A rosin containing solution in ethyl acetate at a mass fraction of 50% was uniformly spin-coated onto the graphene film sample at a rotation speed of 1200 rpm, followed by solidifying at room temperature for 30 min to form a rosin/Gr/Cu stack having a rosin layer.

The tape was peeled off. The rosin/Gr/Cu stack was re-fixed onto the glass plate with the rosin layer contacting the glass plate, and placed into an oxygen plasma cleaner for 20 min to remove graphene on a backside of the Cu foil in the rosin/Gr/Cu stack.

The rosin/Gr/Cu stack was taken from the glass plate, and placed into an ammonium persulfate solution as an etching solution for about 1 h to etch the Cu foil. After the copper foil was completely removed, the sample was washed with deionized water for several times to obtain a rosin/Gr stack.

A silicon wafer having an oxide layer with a thickness of 300 nm was cut into small square pieces with a size of about 1 cm×1 cm. Then, the piece was washed, and treated by oxygen plasma for using as a target substrate.

The rosin/Gr stack was collected onto the target substrate to obtain a rosin/Gr/substrate stack. The rosin/Gr/substrate stack was dried, heated on a heating stage at a temperature of 40° C. for 30 min, and placed into isoamyl acetate as an organic solvent for 20 min to remove the rosin layer so as to obtain a Gr/substrate stack. The Gr/substrate stack was finally dried by nitrogen gas.

FIG. 9 is an optical microscope (OM) image of a graphene film obtained in Comparative Example 2. As can be seen from FIG. 9, particles remaining on a surface of the graphene film transferred by the method in Comparative Example 2 are less than those in Comparative Example 1. This is because the molecular weight of rosin is much less than that of PMMA, such that the binding force between rosin and graphene is weaker, and thus rosin is easy to remove. However, the weaker binding force also leads to insufficient supporting of the rosin supporting layer for the graphene film, which causes structural damages to the graphene film and thus results in a non-integral graphene film.

As compared to the graphene films obtained in Comparative Examples 1 and 2, less cracks and less polymer residues exist on the surface of the graphene film obtained in the Inventive Example 1, which ensures both the neatness and integrity of the graphene film. Moreover, it is also possible to observe wrinkles due to different thermal expansion coefficients of the graphene film and the copper substrate in the growth process. Since the binding force between graphene at the wrinkles and supporting materials is stronger as compared to that between the flat graphene and the supporting materials, remaining polymer residues tend to distribute along the wrinkles on the graphene film. As can be seen from FIG. 4, no CA particles remain even at the wrinkles on the graphene film, which further indicates that a high-quality graphene film can be obtained by the method in the Inventive Example 1. This may be attributed to the smaller average molecular weight of CA and its better solubility in organic solvents.

FIG. 5A and FIG. 5B are X-ray photoelectron spectroscopy (XPS) spectra of graphene films on SiO₂/Si substrates obtained in the Inventive Example 1 and Comparative Example 1, respectively. As can be seen from FIG. 5A and FIG. 5B, peaks of corresponding supporting materials are detected only on the surface of the graphene film transferred by the PMMA supporting layer. In the case of the graphene film transferred by the CA supporting layer, no CA-related XPS peak is found. This further indicates that numerous PMMA particles remain on the surface of the graphene film transferred by the PMMA supporting layer, which, as known, can impair the electrical properties of the transferred graphene film.

To further verify the above effect, sheet resistance distributions of both the graphene films obtained in the Inventive Example 1 and Comparative Example 1 are plotted in FIG. 6A and FIG. 6B, respectively, using exactly the same color bar. For each sample, 100 sheet resistance values were obtained using a 4-probe resistance measurement system, over an area of 20×20 mm² with a step of 2 mm in both directions. The sheet resistance values of the graphene film transferred by the PMMA supporting layer varied from 526 to 914 Ω·□⁻¹ with an average of 753 Ω·□⁻¹. As can be seen from FIG. 6B, spots with abnormally high sheet resistance values are randomly distributed on the surface of graphene film transferred by the PMMA supporting layer, which may be caused by mechanical damages in the transfer process and PMMA particles remaining on the surface of the graphene film. In a sharp contrary, the graphene film transferred by the CA supporting layer exhibits a much narrower fluctuation and smaller sheet resistance values. With sheet resistances varied from 520 to 632 Ω·□⁻¹ and an average value of 603 Ω·□⁻¹, the graphene film transferred by the CA supporting layer shows a homogenous sheet resistance distribution over the whole area of 20×20 mm². Although the sheet resistance in the marginal area is slightly increased, the relatively lower and homogeneous sheet resistance indicates that the graphene film transferred by the CA supporting layer is ultraclean and intact, and thus has more potential in the application of electronic devices.

### INVENTIVE EXAMPLE 2

A method for transferring a hexagonal boron nitride (h-BN) film in the Inventive Example 2 will be described as follows:

A h-BN film sample having a h-BN film and a copper (Cu) foil grown was bonded onto a glass plate with a tape. A cera alba (CA) containing solution in chloroform at a concentration of 0.2 g·mL⁻¹ was uniformly spin-coated onto the h-BN film sample at a rotation speed of 4000 rpm for 120 s, followed by standing at room temperature for 10 min to form a CA/h-BN/Cu stack having a CA layer. The thickness of the CA layer was about 1 μm.

The tape was peeled off. The CA/h-BN/Cu stack was re-fixed onto the glass plate with the CA layer contacting the glass plate, and placed into an oxygen plasma cleaner for 20 min to remove h-BN on the backside of the Cu foil in the CA/h-BN/Cu stack.

The CA/h-BN/Cu stack was taken from the glass plate, and placed into an ammonium persulfate solution as an etching solution for about 1 h to etch the Cu foil. After the copper foil was completely removed, the sample was washed with deionized water for several times to obtain a CA/h-BN stack.

A silicon wafer having an oxide layer with a thickness of 300 nm was cut into small square pieces with a size, i.e., about 1 cm×1 cm. Then, the piece was washed, and treated by oxygen plasma for using as a target substrate, i.e., a SiO₂/Si substrate.

The CA/h-BN stack was collected onto the target substrate to obtain a CA/h-BN/substrate stack. The CA/h-BN/substrate stack was dried, and placed in chloroform as an organic solvent at a temperature of 40° C. to remove the CA layer so as to obtain a h-BN/substrate stack. The h-BN/substrate stack was finally dried by nitrogen gas.

FIG. 11 is an optical microscope (OM) image of a h-BN film obtained in the Inventive Example 2. As shown in FIG. 11, the CA transferred h-BN films have a complete and clean surface similar to the graphene film in the Inventive Example 1.

### COMPARATIVE EXAMPLE 4

A method for transferring a h-BN film in Comparative Example 4 will be described as follows:

A h-BN film sample having a h-BN film and a copper (Cu) foil grown was bonded onto a glass plate with a tape. A PMMA containing solution in anisole at a mass fraction of 4% was uniformly spin-coated onto the h-BN film sample at a rotation speed of 3000 rpm, followed by heating on a heating stage at a temperature of 70° C. for 10 min to form a PMMA/h-BN/Cu stack having a PMMA layer.

The tape was peeled off. The PMMA/h-BN/Cu stack was re-fixed onto the glass plate with the PMMA layer contacting with the glass plate, and placed into an oxygen plasma cleaner for 20 min to remove h-BN on a backside of the Cu foil in the PMMA/h-BN/Cu stack.

The PMMA/h-BN/Cu stack was taken from the glass plate, and placed into an ammonium persulfate solution as an etching solution for about 1 h to etch the Cu foil. After the copper foil was completely removed, the sample was washed with deionized water for several times to obtain a PMMA/h-BN stack.

A silicon wafer having an oxide layer with a thickness of 300 nm was cut into small square pieces with a size of about 1 cm×1 cm. Then, the piece was washed, and treated by oxygen plasma for using as a target substrate.

The PMMA/h-BN stack was collected onto the target substrate to obtain a PMMA/h-BN/substrate stack. The PMMA/h-BN/substrate stack was dried, heated on the heating stage at a temperature of 40° C. for 30 min, and placed into 70° C. acetone as an organic solvent for 30 min to remove the PMMA layer so as to obtain a h-BN/substrate stack. The h-BN/substrate stack was finally dried by nitrogen gas.

FIG. 12 is an optical microscope (OM) image of a h-BN film obtained in Comparative Example 4. In addition to impurities, there are many cracks on the surface of the h-BN film, which may be caused by using the PMMA layer as the supporting layer for the transfer.

Device Fabrication

To fabricate the device, a graphene layer was first transferred onto a SiO₂/Si substrate with a thickness of 300 nm by using a CA supporting layer. Next, the graphene layer was patterned via photolithography and subsequently selectively etched by O₂ plasma to form source and drain electrodes with a gap of 20 μm. PbI₂ was directly grown to bridge the patterned graphene electrodes by a solution method. Then, 30 nm Au electrodes were deposited by thermal evaporation for measurement.

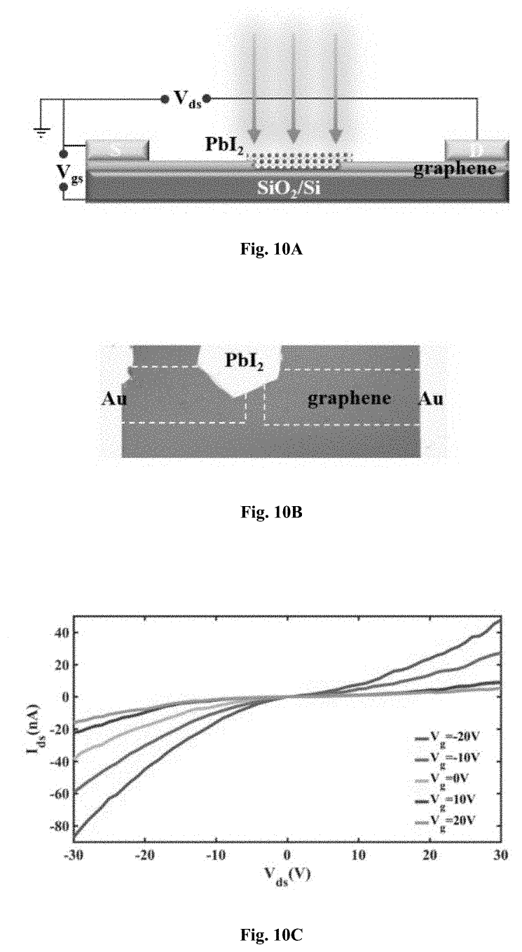

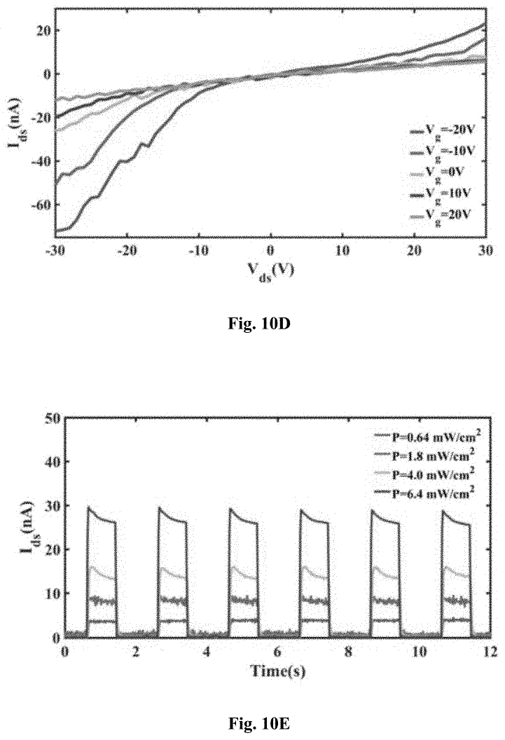

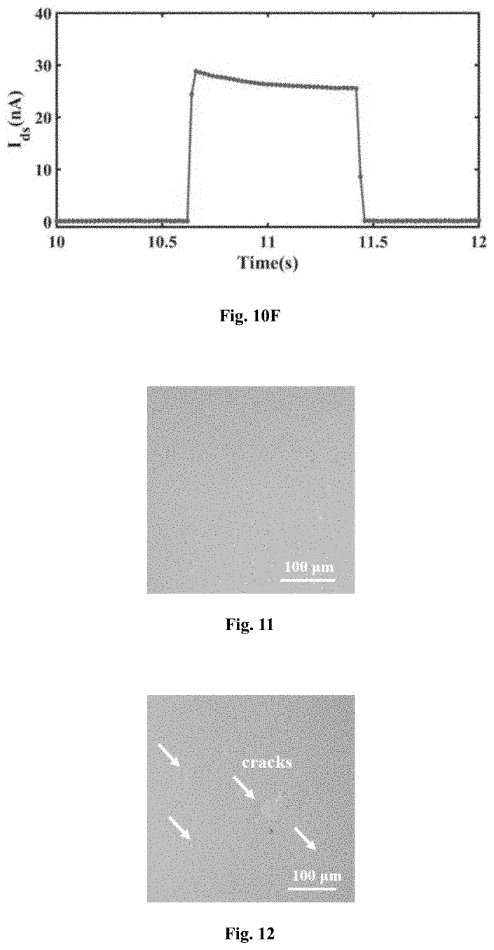

The ultraclean graphene (Gr) layer is applied as a 2D electrode in Gr-PbI₂-Gr photodetector to extract photogenerated carrier and PbI₂ nanoflakes are used for UV light sensing. The schematic illustration of a typical Gr-PbI₂-Gr photodetector is shown in FIG. 10A, in which a 375 nm laser was used as an illumination source. FIG. 10B shows an OM image of a typical Gr-PbI₂-Gr photodetector. The corresponding source-drain current-voltage (I_{ds}-V_{ds}) curves of the Gr-PbI₂-Gr photodetector with different gate biases (Vg) are plotted in FIG. 10C, and I_{ds}-V_{ds} curves of an Au-PbI₂-Au photodetector were also measured in FIG. 10D for comparison with the Gr-PbI₂-Gr photodetector. The phenomenon of current asymmetry in I_{ds}-V_{ds} curves may be caused by the formation of asymmetric Schottky Barrier. It is apparent that the device with ultraclean graphene electrodes exhibit reduced contact resistance and fewer noise signals. For instance, at a same V_{g} of −20 V and source-drain voltage (V_{ds}) of 30 V, the source-drain current (I_{ds}) of the Gr-PbI₂-Gr device is twice as large as that of the Au-PbI₂-Au device.

Devices with PMMA-transferred graphene electrodes were also fabricated. However, the insulating polymer residuals and severe surface roughness of the graphene layer lead to high leakage current and accelerated device failure. This also suggests that the quality of graphene layers is of significance for devices.

To demonstrate the photoresponse properties of the Gr-PbI₂-Gr photodetector, I-t curves were measured with different illumination power densities, as shown in FIG. 10E. With increasing illumination power density, photocurrent (Iₚₕ) increased from 3.8 nA to 27.0 nA. The corresponding responsivity was calculated to be 1200 mAW⁻¹ under the illumination of a 375 nm laser using the formula R=(I_{light}−I_{dark})/(P×S). From the detailed I-t curve measured under V_{ds}=5 V and V_{gs}=0 V in FIG. 10F, the rise time of 17.1 ms and the decay time of 30.6 ms are deduced.

Critical parameters for UV photodetectors based on different materials are compared in Table 1. With ultraclean graphene electrodes, the PbI₂ photodetector shows a significantly higher responsivity than other UV photodetectors. Even compared to other UV photodetectors with the same parameters, high-quality graphene electrodes still enable the PbI₂ photodetector to increase the responsivity by 135% while maintaining a fast response speed.

TABLE 1
Comparison of the critical parameters for UV
photodetectors based on different materials.

| | | λ | Responsivity | Rise time |
|---|---|---|---|---|
| Materials | Electrodes | (nm) | (mAW⁻¹) | (ms) |
| Bi QDs | Solutions | 350 | 0.0193 | \ |
| NiPS₃ | Metal | 254 | 126 | 3.2 |
| PtSe₂/GaN | Metal | 265 | 193 | 0.045 |
| SnS₂ | Metal | 390 | 470 | 150 |
| PbI₂ | Metal | 375 | 510 | 14.1 |
| PbI₂ | Metal | 405 | 410 | 86 |
| PbI₂ | Gr | 375 | 1200 | 17.1 |

In the specification, it is to be understood that terms such as “central,” “longitudinal,” “lateral,” “length,” “width,” “thickness,” “upper,” “lower,” “front,” “rear,” “left,” “right,” “vertical,” “horizontal,” “top,” “bottom,” “inner,” “outer,” “clockwise,” and “counterclockwise” should be construed to refer to the orientation as then described or as shown in the drawings under discussion. These relative terms are for convenience of description and do not require that the present invention be constructed or operated in a particular orientation.

In the present invention, unless specified or limited otherwise, the terms “mounted,” “connected,” “coupled,” “fixed” and the like are used broadly, and may be, for example, fixed connections, detachable connections, or integral connections; may also be mechanical or electrical connections; may also be direct connections or indirect connections via intervening structures; may also be inner communications of two elements, which can be understood by those skilled in the art according to specific situations.

In the present invention, unless specified or limited otherwise, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “above,” or “on top of” a second feature may include an embodiment in which the first feature is right or obliquely “on,” “above,” or “on top of” the second feature, or just means that the first feature is at a height higher than that of the second feature; while a first feature “below,” “under,” or “on bottom of” a second feature may include an embodiment in which the first feature is right or obliquely “below,” “under,” or “on bottom of” the second feature, or just means that the first feature is at a height lower than that of the second feature.

Although terms such as “first”, “second” and “third” are used herein for describing various elements, these elements should not be limited by these terms. These terms are only used for distinguishing one element from another element.

Terms used herein in the description of the present disclosure are only for the purpose of describing specific embodiments, but should not be construed to limit the present disclosure. As used in the description of the present disclosure and the appended claims, “a” and “the” in singular forms mean including plural forms, unless clearly indicated in the context otherwise. It should also be understood that, as used herein, the term “and/or” represents and contains any one and all possible combinations of one or more associated listed items. It should be further understood that, when used in the specification, terms “comprising” and/or “containing” specify the presence of stated features, operations, elements and/or components, but do not exclude the presence or addition of one or more other features, operations, elements, components and/or groups thereof.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present disclosure. Thus, the appearances of the phrases such as “in some embodiments,” “in one embodiment”, “in an embodiment”, “in another example,” “in an example,” “in a specific example,” or “in some examples,” in various places throughout this specification are not necessarily referring to the same embodiment or example of the present disclosure. Furthermore, the particular features, structures, materials, or characteristics may be combined in any suitable manner in one or more embodiments or examples.

Although explanatory embodiments have been shown and described, it would be appreciated by those skilled in the art that the above embodiments cannot be construed to limit the present disclosure, and changes, alternatives, and modifications can be made in the embodiments without departing from spirit, principles and scope of the present disclosure.

What is claimed is:

1. A method for transferring a graphene film, comprising:
spin-coating a cera alba containing solution onto a surface of the graphene film on a metal substrate to form a cera alba layer as a supporting layer, so as to obtain a first stack having the cera alba layer, the graphene film and the metal substrate in sequence;
removing the metal substrate with an etching solution to obtain a second stack having the cera alba layer and the graphene film, transferring the second stack onto a target substrate to obtain a third stack having the second stack and the target substrate, and drying the third stack; and
removing the cera alba layer with an organic solvent to complete a transfer of the graphene film.

2. The method of claim 1, wherein the step of spin-coating the cera alba containing solution onto the surface of the graphene film on the metal substrate to form the cera alba layer comprises:
spin-coating the cera alba containing solution onto the surface of the graphene film at a temperature higher than or equal to 60° C., followed by standing to form the cera alba layer.

3. The method of claim 2, wherein the spin-coating is performed with hot air at a temperature higher than or equal to 60° C.

4. The method of claim 1, wherein a concentration of the cera alba containing solution is less than or equal to 1 g·mL⁻¹.

5. The method of claim 1, wherein the cera alba layer has a thickness less than or equal to 10 μm.

6. The method of claim 1, wherein the etching solution is selected from at least one of an ammonium persulfate solution and a ferric chloride solution.

7. The method of claim 1, wherein the organic solvent is selected from one or more of chloroform, diethyl ether, and benzene.

8. The method of claim 1, wherein the metal substrate is a copper foil, and the target substrate is a SiO₂/Si substrate.

9. The method of claim 1, wherein the cera alba layer is removed with chloroform at a temperature of 40° C.

10. A method for transferring a two-dimensional material film, comprising:
coating a cera alba containing solution onto a surface of the two-dimensional material film on a first substrate to form a first stack having a cera alba layer;
removing the first substrate with an etching solution to obtain a second stack, transferring the second stack onto a target substrate to obtain a third stack; and
removing the cera alba layer with an organic solvent.

11. The method of claim 10, wherein the two-dimensional material film comprises at least one of graphene, transition metal dichalcogenides, hexagonal boron nitride (h-BN), silicene, germanene, black phosphorus (BP), borophene, stannene, transition metal thiophosphates, ternary transition metal chalcogenides, transition metal halides, transition metal carbides, transition metal nitrides, transition metal carbonitrides, layered double hydroxides, metal-organic framework (MOF), antimonene, derivatives thereof, and combinations thereof.

12. The method of claim 10, wherein coating the cera alba containing solution onto the surface of the two-dimensional material film on the first substrate to form the first stack having the cera alba layer comprises:
spin-coating the cera alba containing solution onto the surface of the two-dimensional material film at a temperature higher than or equal to 60° C., followed by standing to form the cera alba layer.

13. The method of claim 12, wherein the spin-coating is performed with hot air at a temperature higher than or equal to 60° C.

14. The method of claim 10, wherein a concentration of the cera alba containing solution is less than or equal to 1 g·mL⁻¹.

15. The method of claim 10, wherein the cera alba layer has a thickness less than or equal to 10 μm.

16. The method of claim 10, wherein the etching solution is selected from at least one of an ammonium persulfate solution and a ferric chloride solution.

17. The method of claim 10, wherein the organic solvent is selected from one or more of chloroform, diethyl ether, and benzene.

18. The method of claim 10, wherein the first substrate is a copper foil, and the target substrate is a SiO₂/Si substrate.

19. The method of claim 10, wherein the cera alba layer is removed with chloroform at a temperature of 40° C.

20. A photodetector, comprising:
a substrate;
a graphene layer formed on at least a part of a surface of the substrate, wherein the graphene layer is transferred onto the at least a part of the surface of the substrate by using a cera alba supporting layer;
a PbI₂ layer formed on a remaining part of the surface of the substrate and connected to the graphene layer; and
a source and a drain formed on a surface of the graphene layer, respectively.
